(19) United States
(12) Patent Application Publication
(10) Pub. No.: US 2025/0389011 A1
(43) Pub. Date: Dec. 25, 2025

(54) DEVICE FOR EVAPORATING OF A COATING MATERIAL AND USE OF IT

(71) Applicants: China Triumph International Engineering Co., Ltd., Shanghai (CN); CTF Solar GmbH, Dresden (DE)

(72) Inventors: Ganhua FU, Shanghai (CN); Shou PENG, Shanghai (CN); Xinjian YIN, Shanghai (CN); Liyun MA, Shanghai (CN); Bastian SIEPCHEN, Dresden (DE); Daniele MENOSSI, Dresden (DE); Thomas ETZRODT, Dresden (DE); Marco SWOBODA, Dresden (DE); Michael BAUER, Dresden (DE)

(73) Assignees: China Triumph International Engineering Co., Ltd., Shanghai (CN); CTF Solar GmbH, Dresden (DE)

(21) Appl. No.: 18/880,254

(22) PCT Filed: Jul. 1, 2022
(86) PCT No.: PCT/CN2022/103337

§ 371 Date: Dec. 30, 2024

(51) Int. Cl. C23C 14/24; C23C 14/54

(52) U.S. Cl. CPC C23C 14/246; C23C 14/243; C23C 14/54

(57) ABSTRACT

Device for evaporation (100) of a coating material comprising a first material reservoir (10), a first pressure—and temperature-sealing metering device (11), a first transportation section (12), a second material reservoir (13), a second pressure—and temperature-sealing metering device (14), a second transportation section (15), and a porous evaporation member (16), all connected in the mentioned order with each other. The device for evaporation (100) further comprises a heater for heating the porous evaporation member (17), a pressure measuring means (21), a sublimation chamber (19) and a cover plate (20). The porous evaporation member (16), the heater and the pressure measuring means (21) are arranged in the sublimation chamber (19), whereas the cover plate (20) terminates the sublimation chamber (19) at its underside. The second pressure—and temperature-sealing metering device (14) is configured to be controlled in dependence on a pressure in the sublimation chamber (19) measured by the pressure measuring means (21).

### FIELD OF TECHNOLOGY

The invention concerns a device for evaporating of a coating material, in particular for solar cell production, and the use of it.

### BACKGROUND

In manufacturing optoelectronic devices, like thin film solar cell devices, light emitting devices, displays and so on, coating materials are often evaporated and deposited under vacuum conditions. “Vacuum” is any pressure lower than normal pressure. However, evaporation and deposition may also be performed under normal pressure or even at higher pressures. Deposition systems including a device for evaporation are known as batch and continuous deposition systems. Usually, these systems at least comprise at least one deposition chamber, means for holding and/or transporting a substrate, means for heating and/or cooling the deposition chamber and/or the substrate, at least one device for evaporating of a coating material, also called an evaporation source, which is suitable for evaporating or sublimating the coating material, means for heating the at least one evaporation source and means for pumping and/or ventilating. The term “evaporation” is usually used as a generic term for all thermally activated phase transitions of a substance into the gas state that occur at the surface of the substance. That is, evaporation often means vaporization, i.e. phase transition of a substance from the liquid phase to vapour, or sublimation, i.e. phase transition of a substance directly from the solid to the gas state without passing through the liquid state. Sublimation is often performed in closed-space sublimation (CSS) systems, sometimes also called close-space sublimation systems. Evaporation systems may be classified in bottom-up and top-down systems.

Bottom-up deposition systems usually include an evaporation source being arranged underneath the substrate to be coated. Such systems are known, for instance, from WO 2010/035130 A2. The evaporation source evaporates the coating material at an upper end of the evaporation source upwards onto the underside of a substrate to be coated. In bottom-up systems, substrate holding respectively transporting is difficult and may cause damages of the substrate or the deposited material layer.

Top-down deposition systems usually include an evaporation source being arranged above the substrate to be coated. Such systems are known, for instance, from KR 10 2015 0017849 A and US 2013/0115372 A1. The evaporation source evaporates the coating material at an upper end of the evaporation source and the evaporated coating material is redirected downwards onto the upper side of a substrate to be coated.

However, in particular for closed space sublimation, there is a need for continuously refilling the coating material into the evaporation source, since the characteristics of a coated film, like thickness and composition of the coated film and the optical or electrical properties of the coated film, should not vary over time of the use of the evaporation source, but depend on the filling level of the evaporation source.

### SUMMARY

Object of the invention is to provide a device for evaporation of a coating material which allows a continuously refilling or coating material and the use of such a device.

The object is solved by a top-down evaporation source and the use of it according to the independent claims. Specific embodiments are subject of the depending claims.

A device for evaporation of a coating material, in particular for solar cell production, according to the invention at least comprises the following components:
a) a first material reservoir for holding granular coating material at a temperature T1 and a pressure p1,
b) a first pressure—and temperature-sealing metering device,
c) a first transportation section,
d) a second material reservoir for receiving granular coating material at a temperature T2 and a pressure p2,
e) a second pressure—and temperature-sealing metering device,
f) a second transportation section with a pressure p3,
g) a porous evaporation member for receiving granular coating material at a temperature T3 and a heater for heating the porous evaporation member to a temperature T4,
h) a sublimation chamber with a pressure p4, in which the porous evaporation member and the heater are arranged, and
i) a cover plate provided with gas outlet openings on an underside of the sublimation chamber.

The components are arranged and connected to one another in the sequence in which they are listed above. The first material reservoir is configured to hold the granular coating material at the temperature T1 and the pressure p1 and may comprise suitable means, like heaters or cooling means or pumps, for achieving T1 and p1. The first material reservoir is arranged and configured to discharge a controllable quantity of granules of the coating material through the first transportation section into the second material reservoir via the first pressure—and temperature-sealing metering device. Or in other words: The first metering device is configured to feed a controllable quantity of granules of the coating material through the first transportation section into the second material reservoir, while sealing the first material reservoir and the first transportation section from each other with respect to temperature and pressure. In the first transportation section as well as in the second material reservoir, the pressure p2 is configured to be set. In the second material reservoir, the temperature T2 is configured to be set, whereas the temperature may vary from T1 to T2 over the extent of the first transportation section. For setting temperature and pressure, the first transportation section and the second material reservoir may comprise suitable means as described above with respect to the first material reservoir. The second material reservoir is arranged to discharge a controllable quantity of granules through the second transportation section into the porous evaporation member via the second pressure—and temperature-sealing metering device. In other words: The second metering device is configured to feed a controllable quantity of granules of the coating material through the second transportation section into the porous evaporation member, while sealing the second material reservoir and the second transportation section from each other with respect to temperature and pressure. Within the second transportation section, the pressure p3 is configured to be set, and the temperature is configured to be set such that the coating material enters the porous evaporation member with the temperature T3, wherein the temperature may vary from T2 to T3 over the extent of the second transportation section. Again, respective suitable means for achieving temperature and pressure may be comprised.

The heater for the porous evaporation member is arranged and configured to generate the temperature T4 in the porous evaporation member, which temperature leads to evaporation of the granular coating material. The heater may be, for instance, a heating lamp, an RF coil, or a resistive heater, made of high temperature suitable metal alloys for instance, or a fluid temperature control system, wherein the heater is placed at a distance from the porous evaporation member as will be described later.

The porous evaporation member is arranged and configured to release the evaporated coating material into the sublimation chamber through the pores of the porous evaporation member. In other words: The evaporated coating material is enabled to enter the sublimation chamber via the pores of the porous evaporation member, while solid particles may not penetrate the porous evaporation member. That is, the porous evaporation member also improves homogeneity of the vapor entering the sublimation chamber and serves as a filter allowing only gaseous particles to penetrate. For this purpose, the porous evaporation member is made at least partially of a porous material, for instance a porous ceramic. The heater is arranged with a distance to the porous evaporation member at least in the regions where the porous evaporation member is made of the porous material such that evaporated coating material may leave the porous evaporation member. The porous evaporation member may be formed as a hollow body having one long extension and one or two shorter extensions, like a hollow cylinder or hollow cuboid or a tube, wherein one or both ends of the body with respect to its long extension may be closed, i.e. not porous. The outer diameter of the porous evaporation member lies in the range of 1 mm to 100 mm, preferably 10 mm to 100 mm and the porous evaporation member has a thickness of its wall of 1 mm to 50 mm, preferably 1 mm to 10 mm. The porous material may have a porosity of 35%, the diameter of the pores lying in the range of 0.1 μm to 50 μm, preferably 1 μm to 20 μm. The porous evaporation member has at least one opening connected to the second transportation section, through which opening the granular coating material enters the porous evaporation member. The porous evaporation member may comprise an accumulation region, in which the introduced granular coating material is configured to accumulate and to be heated until evaporation occurs. That accumulation region may be made of a nonporous material, for instance a nonporous ceramic.

In order to prevent re-condensation of the evaporated coating material, the whole sublimation chamber, i.e. all components arranged in it and all walls including also the cover plate, are held at least at an average temperature near T4, i.e. T4±10%. Heating elements may of course have locally higher temperatures to provide sufficient heat transfer to other components. For this purpose, respective suitable means for controlling the temperature may be comprised.

The cover plate is arranged and configured to allow the evaporated coating material to exit the sublimation chamber through the openings of the cover plate and to be deposited on a surface of a substrate being held or moved beneath the sublimation chamber. Due to evaporation of the coating material and the evaporated coating material exiting the sublimation chamber, the pressure within the porous evaporation member may be higher than the pressure p4 within the sublimation chamber, in particular near the cover plate. The pressure within the porous evaporation member may be equal to p3. The underside of the sublimation chamber means a bottom or side of the sublimation chamber directed towards gravity.

The device for evaporation of a coating material further comprises pressure measuring means arranged in the sublimation chamber for detecting the pressure p4 in the sublimation chamber. At least the second pressure—and temperature-sealing metering device is configured to be controlled in dependence on the pressure p4 in the sublimation chamber.

Advantageously, such a device for evaporation of a coating material enables a continuous and controlled feeding of the coating material and a uniform vapour pressure of the evaporated coating material over time. Furthermore, no carrier gas is needed for supplying the evaporated coating material towards a substrate to be coated and arranged underneath the sublimation chamber.

A coating material according to the invention is any material suitable to be coated onto a substrate and evaporated at a certain pressure and a certain temperature.

The device for evaporation according to the invention is suitable for stationary or continuous deposition processes, preferably for continuous deposition processes, and may be applied in conjunction with a suitable deposition system, in particular with a vacuum deposition system, as described above. Furthermore, the device for evaporation according to the invention is particularly suitable for deposition processes in the course of solar cell production, in particular for sublimation processes like CSS. The device for evaporation according to the invention is suitable for being used in a permanent deposition system, since the coating material is refilled without interrupting the deposition process and no crucible comprising the coating material has to be replaced after a predetermined time period of evaporation like in batch systems.

The first and the second material reservoir each means a space fillable with granular coating material and suitable for holding the contained coating material at a predefined temperature and a predefined pressure. In embodiments, both reservoirs are surrounded by sidewalls and, in case of the first material reservoir, the first metering device or, in case of the second material reservoir, the second metering device. The second material reservoir forms together with the first transportation section and the first and the second metering devices a closed space.

In embodiments, the first or the second material reservoir could be omitted without compromising the functionality described by reasonably enlarging the other reservoir that means the second respectively the first material reservoir and choosing the most appropriate first respectively second pressure and temperature sealing metering device.

The outer form of the material reservoirs as well as the transportation sections is not limited as long these components may satisfy their respective function. That is, outer form of the material reservoirs and the transportation sections may be, for instance, a cylinder with a circular or oval area at the upper end and/or at the lower end, or a prism, e.g. a cuboid, or a truncated cone or a truncated pyramid or any other kind of body.

The first and the second transportation sections may be arranged freely with respect to their orientation in the space, i.e. with respect to vertical or horizontal direction, as long as the transport of the coating material through them is ensured. In some embodiments, the first and/or the second transportation sections may be arranged in a vertical direction such that the coating material falls or drops through it. In other embodiments, the first and/or the second transportation sections may be arranged in an angle larger than 0° (zero degree) with respect to the horizontal line such that the coating material slide through the first and/or second transportation sections. In further embodiments, special transportation means, like conveyors or others, may be arranged within the first and/or the second transportation sections which transportation means support the transport of the coating material through the first and/or the second transportation sections. The first transportation section and the second transportation may be arranged and provided with transportation means in the same way or in different ways.

The first and second material reservoirs, the first and second transportation sections, the first and second metering devices and the sublimation chamber may be made from any material suitable for ensuring the function of the respective components. In embodiments, these components are made of a material inert to the coating material in solid, liquid or gaseous phase. For instance, these components may be made of stainless steel, graphite, ceramic materials or any other suitable material. Furthermore, the materials different components may differ from each other.

Achieving the predefined temperatures in the first and second material reservoir, the first and second transportation section, the porous evaporation member and the sublimation chamber may be achieved by known heating or cooling means, for instance by a heating lamp, an RF coil, or a resistive heater or a fluid temperature control system, wherein these heating or cooling means may be placed on the outside of the respective component or placed at a distance from the respective component or may be even incorporated within the respective component, for instance within sidewalls, or may be arranged inside a respective component, for instance inside the first material reservoir or inside the sublimation chamber. Such heating or cooling means may be physically separated from the respective component, and heat energy is transferred by radiation or air convection at a large distance.

According to the invention, the cover plate forms the bottom of the sublimation chamber. A cover plate according to the invention means a plate-like element of polygonal or round shape suitable for forming a bottom of the sublimation chamber and being suitable for transmitting the evaporated coating material downwards. In embodiments, the cover plate is a quadrangular, preferably rectangular shaped element with a thickness in the range of >0.1 mm to 20 mm.

The cover plate is in direct physical contact to the evaporated coating material. In embodiments, the cover plate is configured to be heatable such that resublimation, i.e. deposition, of vaporized coating material at the cover plate is prevented. Heating of the cover plate may be achieved by known heating means, for instance by a heating lamp, an RF coil, or a resistive heater, wherein these heating means may be placed on the outside of the cover plate or placed at a distance from the cover plate or may be even incorporated within cover plate. Furthermore, the cover plate itself may be a heater, that is, the cover plate comprises a material which heats when electrical current flows through it.

In embodiments, the cover plate is made from graphite, ceramics, or polycrystalline materials such as silicon carbide, preferably graphite.

For transmitting the evaporated coating material towards a substrate to be coated, the cover plate comprises a plurality of gas outlet opening or apertures. Each of the apertures, i.e. openings, has an upper end, i.e. an entrance, arranged on an upper surface of the cover plate, and a lower end, i.e. an exit, arranged on a lower surface of the cover plate. The upper surface of the cover plate is oriented towards the inside of the sublimation chamber and the lower surface of the cover plate is oriented towards the substrate. The openings may have any cross-sectional shape at the upper surface and the lower surface and between them, wherein the cross-sectional shape of the openings at the upper surface and the lower surface may even differ from each other. In embodiments, each of the plurality of apertures may have any cross-sectional shape, like for instance a round or quadrangular shape, wherein the cross-sectional shape of some or of all of the apertures may be the same or may differ from others.

Among others, the plurality of apertures defines the deposition rate onto the substrate. In embodiments, the cross section area of each single aperture of the plurality of apertures is in the range of 0.5 mm2 to 10 mm2, wherein different apertures may have different cross section areas. Furthermore, the apertures may be distributed uniform or nonuniform over the cover plate. In embodiments, the apertures are distributed such that more apertures with a greater summarized cross section are arranged at the circumferential edges of the cover plate to compensate decreased deposition rates towards the edges of the cover plate compared to the center of the cover plate.

According to embodiments, for the temperatures applies: T1<T2<T3<T4. That is, a temperature gradient along the extension of the device for evaporation is formed with highest temperature in the porous evaporation member and the sublimation chamber. In embodiments, T1 is around 25° C. or room temperature, T2 is around 300° C., T3 is around 400° C. and T4 is in the range of 700° C. to 1000° C. depending on the type of coating material and its material specific sublimation or evaporation temperature. The temperature gradient comprises a lowest temperature at an upper end of the device for evaporation, i.e. in the first material reservoir. Advantageously, this enables continuous refilling the first material reservoir with solid granular coating material at the cold, upper end of the device for evaporation and therefore uninterrupted deposition processes. Furthermore, the coating material may be heated continuously on its way from feeding in the first material reservoir to its evaporation in the porous evaporation member.

In embodiments, the temperature gradient between T1 and T4 comprises temperatures in the range of 675 K to 975 K.

In embodiments, the pressures p1 to p3 may be the same, for instance 1000 Pa, wherein the porous evaporation member may be equal to p3. In other embodiments, at least one of the pressures p1 to p3 may differ from the other ones. For example, p1 and p2 may lie in the range of 100 Pa to 1000 Pa, and p3 may be 1000 Pa. As described above, p4 within the sublimation chamber near the cover plate may be lower than p3, for instance 5 Pa.

In embodiments, the first material reservoir has a closable filling opening for filling in the granular coating material.

Advantageously, the pressure p1 may be adjusted as described above, i.e. lower than normal pressure.

In embodiments, the first pressure—and temperature-sealing metering device is a rotary feeder as known from the prior art.

The first pressure—and temperature-sealing metering device is configured to roughly dose a smaller quantity of the granular coating material to the following sections, i.e. the first transportation section and following components, from the first material reservoir. On the other hand, the first pressure—and temperature-sealing metering device is still suitable enough to stop the material feeding and so the deposition process in a reasonable short time.

In embodiments, the second pressure—and temperature-sealing metering device is a rotary feeder, a valve, a pinch cock, an adjustable orifice or an adjustable constriction of flow diameter.

Advantageously, the second pressure—and temperature-sealing metering device serves as a fine feeder providing only small quantities of the granule coating material into porous evaporation member via the second transportation section. Therefore, the coating material arriving in the porous evaporation member may evaporate very fast, almost instantly. Thus, coating material filled first into the device for evaporation may evaporate first (first in-first out). Furthermore, the second pressure—and temperature-sealing metering device may be adjusted with respect to the quantity of fed coating material very quickly and easily such that a desired pressure p4 is reached in the sublimation chamber. For instance, the aperture or an orifice of the second pressure—and temperature-sealing metering device may be tuned.

In embodiments, the measured values of the pressure measuring means are transmitted to a data processing device which carries out the control of the second and optionally also of the first pressure—and temperature-sealing metering device. That is, the device for evaporation further comprises the data processing device suitable for receiving the measured values of the pressure measuring means and for controlling the second and optionally also of the first pressure—and temperature-sealing metering device.

The data processing device thus serves as a control device for controlling at least the operation of the second metering device in dependence on the output signal of the pressure measuring means. Moreover, further components of the device for evaporation of a coating material, e.g. the first metering device, one or more heaters or pumps, may be controlled by the same or another data processing device in dependence on the output signal of the pressure measuring means.

In embodiments, the data processing device also takes over the further control of the device, in particular of the heater, and in that further sensors are arranged in the device for this purpose, in particular temperature sensors in the sublimation chamber and/or the porous evaporation member.

That is, the device for evaporation further comprises at least one further sensor, e.g. a temperature sensor arranged in the sublimation chamber or the porous evaporation member, and the data processing device is further suitable for controlling at least the heater suited for heating the porous evaporation member in dependence on the output of the at least one further sensor.

In embodiments, the heater is arranged substantially parallel to the longitudinal axis of the porous evaporation member on one or more sides of the porous evaporation member. The longitudinal axis is an axis parallel to the longer extension of the porous evaporation member.

Advantageously, the porous evaporation member may be heated effectively.

In embodiments, the longitudinal axis of the porous evaporation member is oriented vertically and the upper end is open and connected to the second transportation section that introduces the granular coating material; the lower end of the porous evaporation member is closed. That is, the porous evaporation member is formed like a deep pot having a small diameter. The upper end of the porous evaporation member is formed as an opening connected to the second transportation section, wherein granular coating material may be introduced into the porous evaporation member through the opening. The bottom or lower end of the porous evaporation member is formed as a closed wall. The porous evaporation member of these embodiments is made of a porous material at least at the side walls of the porous evaporation member extending vertically.

In embodiments where the porous evaporation member is oriented vertically, alternating deflectors are arranged on the inner wall of the porous evaporation member, which reflect the incident particles of the granular coating material several times, so that the flight distance in the porous evaporation member is extended and/or the incident particles of the granular coating material are slowed down on their way to the lower end of the porous evaporation member. That is, the alternating deflectors extend from the inner wall of the porous evaporation member into the inside of the porous evaporation member and downwards with an angle smaller than 90° measured to the inner wall of the porous evaporation member beneath a respective deflector. The angle is preferably in the range of >0° to ≤90°, preferably 15° to 70°. The deflectors preferably extend over the longitudinal axis, i.e. the middle, of the porous evaporation member with respect to the short extension of the porous evaporation member, but not to the opposite inner wall of the porous evaporation member. The deflectors are formed and arranged such that no direct transportation path from the upper end of the porous evaporation member to the lower end of the evaporation member is provided for the arriving granular coating material.

The deflectors are suited to reflect the incident particles of the granular coating material several times. Thus, the flight distance in the porous evaporation member, i.e. the flying path of the incident particles of the granular coating material within the porous evaporation member, is extended. In the result, the incident coating material is further crushed into even smaller particles and heated more uniformly, and may even be evaporated in upper regions of the porous evaporation member instead only at the lower end of the porous evaporation member. Therefore, evaporated coating material leaves the porous evaporation member over a large amount of the whole longitudinal extension of the porous evaporation member.

In embodiments, the longitudinal axis of the porous evaporation member is arranged horizontally, and the porous evaporation member has an inlet opening between the ends, which inlet opening is connected to the second transportation section that introduces the granular coating material, wherein the porous evaporation member is closed at both ends.

The ends of the porous evaporation member are now arranged in a horizontal line. The porous evaporation member may now be made of a porous material over its whole extension. In embodiments, the porous evaporation member is not made of a porous material only at a position opposite to the inlet opening. Granular coating material is suited to be introduced into the porous evaporation member through the inlet opening during operation of the device for evaporation.

In embodiments, a plurality of components a) to g) are associated with a common sublimation chamber. That is, for instance a plurality of porous evaporation members is arranged within one sublimation chamber, wherein each individual porous evaporation member is connected with an individual sequence comprising a first material reservoir, a first pressure—and temperature-sealing metering device, a first transportation section, a second material reservoir, a second pressure—and temperature-sealing metering device and a second transportation section, and wherein an individual heater for heating the individual porous evaporation member is arranged and associated with each individual porous evaporation member. A plurality of components a) to g) means at least one of each component a) to g), wherein the components are selected independently form each other.

This arrangement enables simultaneously evaporating the same coating material through the plurality of porous evaporation members and thus increasing the amount of evaporated coating material within the sublimation chamber. Thus, the deposition rate of the coating material may be increased. In other embodiments, this arrangement enables simultaneously evaporating different coating materials through the plurality of porous evaporation members and thus providing a mixed or composite evaporated coating material or a doped evaporated coating material in the sublimation chamber, wherein the composition or the doping content of the evaporated (and later deposited) coating material may be adjusted precisely. In particular, coating materials having different evaporation temperatures (meaning also sublimation temperatures) may be evaporated simultaneously.

In further embodiments, a plurality of components a) to g) are associated with a common sublimation chamber, also meaning that a plurality of porous evaporation members is arranged within one sublimation chamber, wherein each individual porous evaporation member is connected with at least two individual sequences comprising each a first material reservoir, a first pressure—and temperature-sealing metering device, a first transportation section, a second material reservoir, a second pressure—and temperature-sealing metering device and a second transportation section, and wherein an individual heater for heating the individual porous evaporation member is arranged and associated with each individual porous evaporation member. This enables mixing for instance of different coating materials or of coating and doping materials within the porous evaporation member.

In embodiments, a plurality of components a) to g) are associated with a common sublimation chamber, meaning also that a plurality of porous evaporation members is arranged within one sublimation chamber, wherein each individual porous evaporation member is connected with a second transportation section. The second transportation section again is connected with at least two individual sequences comprising each a first material reservoir, a first pressure—and temperature-sealing metering device, a first transportation section, a second material reservoir, a second pressure—and temperature-sealing metering section, and wherein an individual heater for heating the individual porous evaporation member is arranged and associated with each individual porous evaporation member. This enables mixing of different coating materials or coating and doping materials already in the second transportation section.

In embodiments, the first material reservoirs associated with different individual porous evaporation members are suitable for receiving the same or also different coating materials.

In embodiments, a plurality of components b) to g) are assigned to a common first material reservoir, the porous evaporation members being arranged in one sublimation chamber or in different sublimation chambers. That is, a plurality of porous evaporation members is arranged within one sublimation chamber, wherein each individual porous evaporation member is connected with an individual sequence comprising a first pressure—and temperature-sealing metering device, a first transportation section, a second material reservoir, a second pressure—and temperature-sealing metering device and a second transportation section, and wherein an individual heater for heating the individual porous evaporation member is arranged and associated with each individual porous evaporation member. However, in contrast to the embodiments described above, all of these individual porous evaporation members and their individual sequence of components are connected to one and the same first material reservoir. Or in other words, a plurality of first pressure—and temperature sealing metering devices is connected to one first material reservoir.

This arrangement enables simultaneously evaporating the same coating material through the plurality of porous evaporation members and thus increasing the amount of evaporated coating material within the sublimation chamber. Thus, the deposition rate of the coating material may be increased.

The invention further refers to the use of a device for evaporation according to the invention for coating of a surface of a substrate with the coating material by moving or placing the substrate under the gas outlet openings of the cover plate. That is, the device for evaporation according to the invention is used as a top-down evaporation device in a deposition process of a coating material to a surface of a substrate arranged beneath the device for evaporation.

In embodiments, the substrate is a substrate for a thin-film solar cell. “Substrate” here means any kind of semi-finished thin-film solar cell, i.e. a thin-film solar cell at any stage of production as long as a layer needs to be deposited on the surface of the semi-finished solar cell by evaporation. In particular, the substrate may be a substrate, e.g. a transparent substrate like a glass or an opaque substrate, wherein the substrate may not comprise any further layers or may already comprise at least one of an electrode layer, e.g. a transparent electrode layer or an opaque electrode layer, or any buffer layer or any absorber layer.

The invention further refers to a method for evaporation a coating material using the device for evaporation according to the invention. The method comprises
filling a granular coating material into the first material reservoir and holding the granular coating material in the first material reservoir at a temperature T1 and a pressure p1,
discharging a first quantity of granules from the first material reservoir through the first transportation section into the second material reservoir via the first pressure—and temperature-sealing metering device,
holding the received quantity of granules in the second material reservoir at a temperature T2 and a pressure p2,
discharging a second quantity of granules of the coating material from the second material reservoir through the second transportation section into the porous evaporation member via the second pressure—and temperature-sealing metering device,
controlling the temperature in the second transportation section such that the granules of the coating material have a temperature T3 when arriving in the porous evaporation member and controlling the pressure in the second transportation section to a pressure p3,
heating the porous evaporation member to a temperature T4 thereby evaporating the coating material, wherein the evaporated coating material leaves the porous evaporation member through the pores of the porous evaporation member being made of the porous material and enters the sublimation chamber,
discharging the evaporated coating material from the sublimation chamber through the openings of the cover plate, and
detecting a pressure p4 in the sublimation chamber by the pressure measuring means arranged in the sublimation chamber and controlling the second pressure—and temperature-sealing metering device in dependence on the detected pressure p4.

Thus, the granular coating material to be evaporated is fed into the porous evaporation member through two material reservoirs, two metering devices and two transportation sections, wherein the coating material will be preheated on its way from the first material reservoir into the porous evaporation member. The temperature and the pressure in the different sections of this way, i.e. in the first material reservoir, in the first transportation section and the second material reservoir, and in the second transportation section, may be adjusted separately, since the first and the second metering devices are pressure—and temperature-sealing metering devices. Furthermore, the pressure p4 within the sublimation chamber, which pressure p4 depends on the amount of evaporated coating material present within the sublimation chamber, may be adjusted by controlling the second pressure—and temperature sealing metering device, i.e. by controlling the second quantity of granules of the coating material discharged from the second material reservoir through the second transportation section into the porous evaporation member via the second pressure—and temperature-sealing metering device. In the result, the amount of evaporated coating material leaving the sublimation chamber through the openings of the cover plate and thus the deposition rate of the coating material on a substrate may be controlled precisely.

For realization of the invention, it is advantageous to combine the described embodiments and features of the claims as described above. However, the embodiments of the invention described in the foregoing description are examples given by way of illustration and the invention is nowise limited thereto. Any modification, variation and equivalent arrangement should be considered as being included within the scope of the invention.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments dis-cussed herein. Therefore, it is intended that this invention is limited only by the claims and the equivalents thereof.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1 shows a schematic illustration of a first embodiment of the device for evaporation according to the invention,

FIG. 2A shows a schematic illustration of a second embodiment of the device for evaporation according to the invention,

FIG. 2B shows a view on the sublimation chamber of FIG. 2A along line A-A,

FIG. 3A shows an exemplary embodiment of the sublimation chamber in a cross section along a first direction,

FIG. 3B shows a view on the sublimation chamber of FIG. 3A along a line B-B,

FIG. 4A shows a schematic illustration of a third embodiment of the device for evaporation according to the invention, and

FIG. 4B shows a view on an exemplary embodiment of the arrangement of porous evaporation members and heaters in a sublimation chamber according to the third embodiment.

### REFERENCE NUMERALS

100, 101, 102 Device for evaporation
10, 10a-10c First material reservoir
11 first pressure—and temperature-sealing metering device
12 first transportation section
13 Second material reservoir
14, 14a-14c second pressure—and temperature-sealing metering device
15 second transportation section
16, 16a-16c Porous evaporation member
17, 17a-17d Heater for the porous evaporation member
18 deflector
19 Sublimation chamber
20 Cover plate
21 pressure measuring means
22 data processing device
23 Body
24 Inlet opening
25 sealing
26 Emission space
110b Feeding and evaporation arrangement
200 Granular coating material in the first material reservoir
201, 201a—Granular coating material in the porous evaporation member 201c

### DETAILED DESCRIPTION

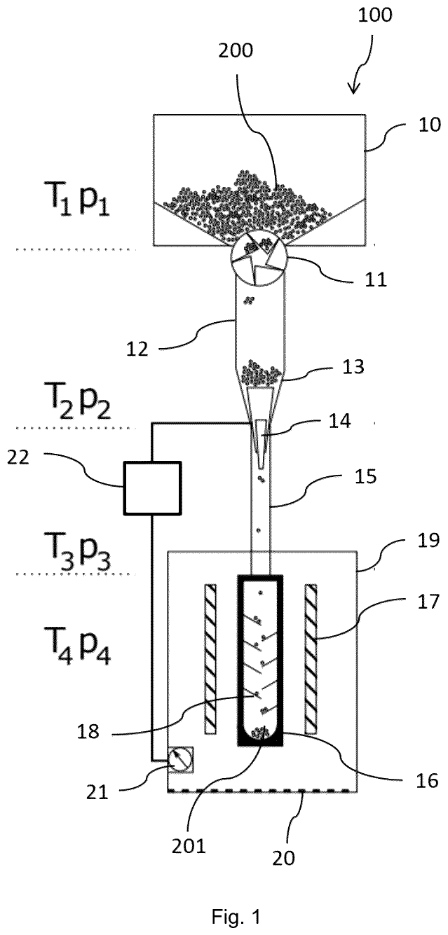

FIG. 1 shows a schematic illustration of a first embodiment 100 of the device for evaporation according to the invention. The device 100 for evaporation comprises a first material reservoir 10, a first pressure—and temperature-sealing metering device 11, a first transportation section 12, a second material reservoir 13, a second pressure—and temperature-sealing metering device 14, a second transportation section 15, a porous evaporation member 16, at least one heater 17, a sublimation chamber 19, a cover plate 20, a pressure measuring means 21 and a data processing device 22.

A granular coating material 200 is held in the first material reservoir 10 at a temperature T1 and a pressure p1. The first pressure—and temperature-sealing metering device 11 feeds granules of the coating material 200 into the second material reservoir 13 via the first transportation section 12 while sealing the first material reservoir 10 from the first transportation section 12 and the second material reservoir 13 with respect to temperature and pressure. The fed granules of the coating material 200 are hold in the second material reservoir 13 at a temperature T2 and a pressure p2. The pressure p2 is also present in the first transportation section 12, whereas the temperature may have a gradient from T1 to T2 over the extension of the first transportation section 12 between the first pressure—and temperature-sealing metering device 11 and the second material reservoir 13. The second pressure—and temperature-sealing metering device 14 feeds granules of the coating material 200 into the porous evaporation member 16 via the second transportation section 15 while sealing the second material reservoir 13 from the second transportation section 15 with respect to temperature and pressure. The pressure within the second transportation section 15 is p3, and the temperature may have a gradient from T2 to T3 over the extension of the second transportation section 15 between the second pressure—and temperature-sealing metering device 14 and an entrance into the porous evaporation member 16.

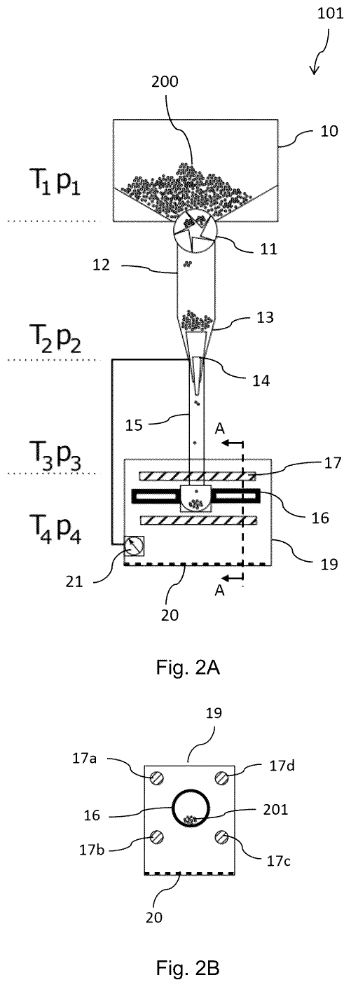

The porous evaporation member 16 is connected with the second transportation section 15 such that granules of the coating material 200 may enter the porous evaporation member 16. The granules of the coating material 200 enter the porous evaporation member 16 with the temperature T3. The porous evaporation member 16 is surrounded by at least one heater 17 which is arranged with a predefined distance to the porous evaporation member 16 and heats the coating material within the porous evaporation member 16 to a temperature T4 at which the coating material evaporates. That is, T4 is equal to or higher than the evaporation or sublimation temperature of the coating material. The porous evaporation member 16 has a long extension along its longitudinal axis which is arranged vertically in the first embodiment 100 of the device for evaporation and the heater 17 is arranged in parallel to the longitudinal axis of the porous evaporation member 16. An upper end of the porous evaporation member 16 is open and forms the entrance for the granules of the coating material 200 into the porous evaporation member 16. A lower end of the porous evaporation member 16 is closed and forms an accumulation region for granules of the coating material not being evaporated on their way downwards. That is, granular coating material 201 may be held in the accumulation region at the bottom of the porous evaporation member 16 until it is fully evaporated. The granular coating material 201 may be the same as the granular coating material 200 in the first material reservoir 10 (shown in FIG. 2A), but may also differ with respect to the size or shape of granules due to the passage of the granular coating material 200 through the first and the second pressure—and temperature-sealing metering device 11, 14. Therefore, even the granules entering the porous evaporation member 16 at the upper end of the porous evaporation member 16 may be granules of the granular coating material 201 instead of the granular coating material 200.

In the inside of the porous evaporation member 16, deflectors 18 are arranged, wherein the deflectors 18 extend from an inner wall of the porous evaporation member 16 to the inside at an angle larger than 0° (zero) and smaller than 90°, wherein the angle is measured downwards.

The deflectors 18 extending from opposite inner side walls of the porous evaporation member 16 are arranged alternating and deflect the inclining granules of the coating material such that their way within the porous evaporation member 16 increases. Thus, the coating material may even evaporate before reaching the lower end of the porous evaporation member 16. The porous evaporation member 16 and the heater 17 are arranged within the sublimation chamber 19. Side walls of the porous evaporation member 16, the side walls extending along the longitudinal axis of the porous evaporation member 16, are formed of a porous material such that evaporated coating material may penetrate them and may enter the sublimation chamber 19.

In order to prevent re-deposition, i.e. condensation, of the evaporated coating material, the temperature within the sublimation chamber 19 is held at T4. The evaporated coating material, i.e. the gaseous coating material particles, leave the sublimation chamber 19 via openings in the cover plate 20 and deposit on a surface of a substrate (not shown) beneath the cover plate 20. Within the sublimation chamber 19, a pressure p4 is present which depends on the amount of gaseous coating material particles within the atmosphere inside the sublimation chamber 19. The pressure measuring means 21 arranged within the sublimation chamber 19 measures the pressure p4 and transmits its measurement result to the data processing device 22 which controls the second pressure—and temperature-sealing metering device 14 in dependence on the pressure p4. In particular, the amount of granular coating material 200 fed into the porous evaporation member 16 from the second material reservoir 13 by the second pressure—and temperature-sealing metering device 14 is controlled. Measurement data and control signals transmitted between the pressure measuring means 21 and the data processing device 22 and the data processing device 22 and the second pressure—and temperature-sealing metering device 14 may be transmitted via wire or wireless.

The device 100 for evaporation may comprise further sensors, e.g. temperature sensors or further pressure sensors, which may also transmit their measuring results to the data processing device 22, which in turn may control further components in dependence on the measuring results. Such further components may be, for instance, the heater 17, further heaters, the first pressure—and temperature-sealing metering device 11 or pumps.

Although the first and the second transportation sections 12 and 15 are arranged vertically in the device 100 for evaporation shown in FIG. 1, they may also be arranged in an oblique angle with respect to the vertical and the horizontal lines in other embodiments, as long as the transport of the granular coating material 200 is guaranteed, for instance by sliding instead of dropping or falling down.

FIG. 2A shows a schematic illustration of a second embodiment 101 of the device for evaporation according to the invention. The device 101 for evaporation differs from the device 100 for evaporation shown in FIG. 1 in that the porous evaporation member 16 is arranged horizontally. That is, the longitudinal axis of the porous evaporation member 16 extends horizontally instead of vertically. The porous evaporation member 16 has an inlet opening connected with the second transportation section 15 and suited for receiving the granular coating material 200 fed by the second pressure—and temperature-sealing metering device 14. This will be explained in more detail later. The lateral ends of the porous evaporation member 16, i.e. the ends with respect to the longitudinal axis, are closed.

Although FIG. 2A does not show a data processing device, the device 101 for evaporation may also comprise such a data processing device which may be a single component or may be a part of the pressure measuring means 21 or of the second pressure—and temperature-sealing metering device 14.

FIG. 2B shows a view on the sublimation chamber 19 of FIG. 2A along line A-A. As can be seen, the porous evaporation member 16 is a tube having a circular cross-section, wherein granular coating material 201 is accumulated at a lower side of the porous evaporation member 16. The porous evaporation member 16 is surrounded by four heaters 17a to 17d, which are arranged with a distance to the porous evaporation member 16.

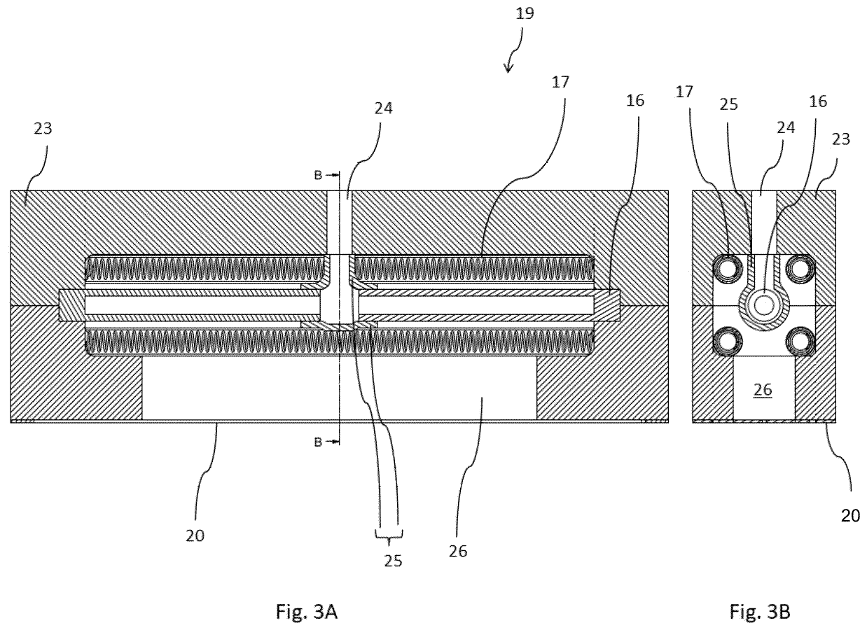

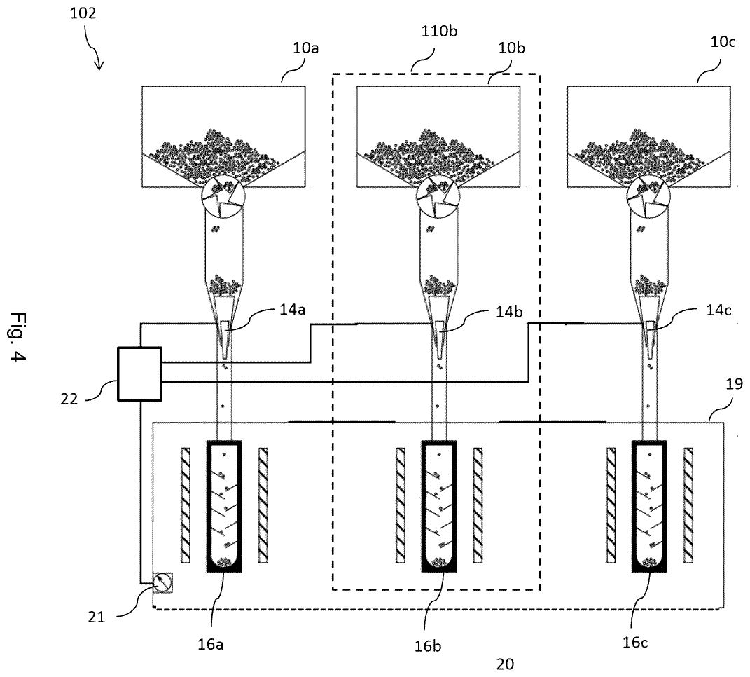

FIG. 3A shows an exemplary embodiment of the sublimation chamber 19 suitable for the use in the device 101 of FIG. 2A in a cross section along a first direction. The first direction is a horizontal direction. FIG. 3B shows a view on the sublimation chamber of FIG. 3A along a line B-B, i.e. along a second direction being also a horizontal direction, but being perpendicular to the first direction. The sublimation chamber 19 is formed of a body 23 made of graphite. The porous evaporation member 16 is held at its lateral ends, i.e. its ends along the longitudinal axis of the porous evaporation member 16, by the body 23. An inlet opening 24 is formed within the body 23 and within the porous evaporation member 16. A sealing 25 is arranged between the body 23 and the porous evaporation member 16 such that the inside of the porous evaporation member 16 is only open to the inlet opening 17, but not to an emission space 26 of the sublimation chamber 19. The emission space 26 is that space into which the evaporated coating material is introduced from the inside of the porous evaporation member 16 via the pores of the porous material of the porous evaporation member 16. The emission space 26 is terminated by the cover plate 20 at its lower end. The sealing 25 does not to be gas tight, but has to hinder solid particles from penetrating. The lower portion of the sealing 25 may serve as the accumulation region of the porous evaporation member 16 as described above. Furthermore, the porous evaporation member 16 may even be formed from two individual tube parts, each part being closed at only one end, wherein the open ends of the two parts are connected by the sealing 25. The porous evaporation member 16 is surrounded by four heaters 17. The pressure measuring means 21 which is also arranged within the emission space 26 is not shown in FIGS. 3A and 3B.

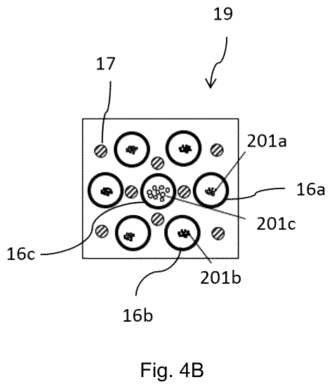

FIG. 4A shows a schematic illustration of a third embodiment 102 of the device for evaporation according to the invention. The device 102 for evaporation comprises three feeding and evaporation arrangements 110b. Each feeding and evaporation arrangement 110b comprises a first material reservoir 10a to 10c, a first pressure—and temperature-sealing metering device, a first transportation section, a second material reservoir, a second pressure—and temperature-sealing metering device 14a to 14c, a second transportation section, a porous evaporation member 16a to 16c, and at least one heater, wherein the components of each individual feeding and evaporation arrangement 110b are connected with each other in the order described above, for instance with respect to FIG. 1. In FIG. 4A, one feeding and evaporation arrangement 110b is referenced by the dashed frame. However, some heaters may also be shared by different feeding and evaporation arrangements 110b. The porous evaporation members 16a to 16c and the associated heaters are arranged in one common sublimation chamber 19. Thus, the same or different coating materials provided in the individual first material reservoirs 10a to 10c may be evaporated and entered into the sublimation chamber 19 in individual amounts. In this way, a desired composition of a gas leaving the sublimation chamber 19 via the cover plate 20 may be achieved. The data processing device 22 is suited for controlling all individual second pressure—and temperature-sealing metering device 14a to 14c in dependence on a measuring result of the pressure measuring means 21 or of further sensors arranged within the sublimation chamber 19.

FIG. 4B shows a view on an exemplary embodiment of the arrangement of porous evaporation members 16a to 16c and heaters 17 of different feeding and evaporation arrangements as described with respect to FIG. 4A in a sublimation chamber 19. That is, the arrangement shown in FIG. 4B may be realized in a device 102 for evaporation according to the third embodiment. In the sublimation chamber 19, six porous evaporation members are arranged in a circle around a seventh porous evaporation member. The outer evaporation members, two of them being referenced by 16a and 16b, may evaporate two different coating materials 201a and 201b, for instance Cd and Te, wherein the porous evaporation members associated to different coating materials are arranged alternatingly. The seventh porous evaporation member 16c in the middle may evaporate a third coating material 201c, for instance a doping material like Se. The heaters 17 may be arranged around and in between the porous evaporation members 16a to 16c such that the desired evaporation temperatures, i.e. the temperatures necessary for evaporating or sublimating the different coating materials, are reached for the respective porous evaporation members 16a to 16c.

What is claimed is:

1. Device for evaporation of a coating material for solar cell production, comprising at least the following components:
a) a first material reservoir for holding granular coating material at a temperature T1 and a pressure p1,
b) a first pressure—and temperature-sealing metering device,
c) a first transportation section,
d) a second material reservoir for receiving granular coating material at a temperature T2 and a pressure p2,
e) a second pressure—and temperature-sealing metering device,
f) a second transportation section with a pressure p3,
g) a porous evaporation member for receiving granular coating material at with a temperature T3 and a heater for heating the porous evaporation member to a temperature T4,
h) a sublimation chamber with a pressure p4, in which the porous evaporation member and the heater are arranged,
i) a cover plate provided with gas outlet openings on an underside of the sublimation chamber,
the components being arranged and connected to one another in the sequence a) to g), characterized in that
the first material reservoir is arranged to discharge a controllable quantity of granules through the first transportation section into the second material reservoir via the first pressure—and temperature-sealing metering device,
the second material reservoir is arranged to discharge a controllable quantity of granules through the second transportation section into the porous evaporation member via the second pressure—and temperature-sealing metering device,
the heater for the porous evaporation member is arranged to generate a temperature in the porous evaporation member which leads to evaporation of the granular coating material,
the porous evaporation member is arranged to enable the evaporated coating material to enter the sublimation chamber through the pores of the porous evaporation member,
the cover plate is arranged to allow the evaporated coating material to exit through the openings of the cover plate,
pressure measuring means are arranged in the sublimation chamber for detecting the pressure in the sublimation chamber, the second pressure—and temperature-sealing metering device being controlled in dependence on the pressure in the sublimation chamber.

2. Device according to claim 1, characterized in that for the temperatures applies: T1<T2<T3<T4.

3. Device according to one of the preceding claims, characterized in that the first pressure—and temperature-sealing metering device is a rotary feeder.

4. Device according to one of the preceding claims, characterized in that the second pressure—and temperature-sealing metering device is a rotary feeder, a valve, a pinch cock, an adjustable orifice or an adjustable constriction of flow diameter.

5. Device according to one of the preceding claims, characterized in that the measured values of the pressure measuring means are transmitted to a data processing device which carries out the control of the second and optionally also of the first pressure—and temperature-sealing metering device.

6. Device according to one of the preceding claims, characterized in that the data processing device also takes over the further control of the device, in particular of the heater, and in that further sensors are arranged in the device for this purpose, in particular temperature sensors in the sublimation chamber and/or the porous evaporation member.

7. Device according to one of the preceding claims, characterized in that the heater is arranged substantially parallel to the longitudinal axis of the porous evaporation member on one or more sides of the porous evaporation member.

8. Device according to any one of the preceding claims, characterized in that the longitudinal axis of the porous evaporation member is oriented vertically and the upper end is open and connected to the second transportation section that introduces the granular coating material; the lower end of the porous evaporation member is closed.

9. Device according to any one of claims 1 to 8, characterized in that alternating deflectors are arranged on the inner wall of the porous evaporation member, which reflect the incident particles of the granular coating material several times, so that the flight distance in the porous evaporation member is extended.

10. Device according to any one of claims 1 to 7, characterized in that the longitudinal axis of the porous evaporation member is arranged horizontally, and the porous evaporation member has an inlet opening between the ends which is connected to the second transportation section that introduces the granular coating material, wherein the porous evaporation member is closed at both ends.

11. Device according to any one of the preceding claims, characterized in that a plurality of components a) to g) are associated with a common sublimation chamber.

12. Device according to claim 11, characterized in that the first material reservoirs are suitable for receiving the same or also different coating materials.

13. Device according to any one of claims 1 to 10, characterized in that a plurality of components b) to g) are assigned to a common first material reservoir, the porous evaporation members being arranged in the same one sublimation chamber or in different sublimation chambers.

14. Usage of a device according to one of the preceding claims for coating of the surface of a substrate with coating material by moving or placing the substrate under the gas outlet openings of the cover plate.

15. Usage according to claim 14, characterized in that the substrate is a substrate for a thin-film solar cell.
